(19) United States
(12) Patent Application Publication
(10) Pub. No.: US 2008/0304236 A1
(43) Pub. Date: Dec. 11, 2008

(54) Maintaining cooling system air above condensation point

(76) Inventors: Vance B. Murakami, Los Gatos, CA (US); Wesley H. Stelter, San Bruno, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/810,269

(22) Filed: Jun. 5, 2007

(51) Int. Cl. H05K 7/20; F25B 29/00

(52) U.S. Cl. 361/699; 361/695; 165/253

(57) ABSTRACT

A cooling system cools air that flows through an electronic system to cool heat generating components. The cooling system maintains a temperature of the air near a set point above a condensation point.

### BACKGROUND

Electronic systems typically have electronic components that generate considerable heat during operation. Some of these components can be damaged or can damage surrounding components or can suffer reduced performance if allowed to become too hot. It is, therefore, necessary to provide cooling for these components.

Typically, cooling is performed by passing air through the electronic system and around the heat generating components. The heat is transferred from the heat generating components to the air. Cooling systems for some electronic systems then pass the heated air to a heat exchanger to cool the air back down. The cooled air is then passed back to the electronic system to repeat this cycle.

If the cooling system cools the air too much, then (among other potential problems) condensation can occur in the heat exchanger, in air passageways or even in the electronic system. It is very undesirable, however, to have water in electronic systems. In fact, in enterprises which have a room containing many electronic systems (e.g. densely packed computer systems and computer-related devices) in rows of rack cabinets, it is preferable not to have any water in the entire room. Such water can potentially corrode some parts of the electronic systems or short out electrical signals. In other words, water can damage the electronic systems or otherwise render the electronic systems inoperative, thereby grinding to a halt a potentially critical function of the enterprise. If this detrimental result occurs, then considerable time and money must be expended to repair or replace the electronic systems and to remedy the conditions that allowed the undesirable situation to occur.

If water can potentially enter an electronic system or a room containing several such systems, then it is necessary to have some means to isolate the water from the electronic system(s). For example, a drip pan may have to be installed under the electronic system to contain the water and prevent it from spreading. Also, if the amount of water can continue to increase in (or in the vicinity of) the electronic system, then it is further necessary to have some means to remove the water to prevent the water from overflowing its containment. For example, a pump and plumbing system may have to be installed in the room containing the electronic systems to pump the water out of the room.

Such containment and removal measures take up space in the room, thereby limiting the space available for the electronic systems. It also costs time and money to install and maintain the water containment and removal apparatuses, thereby adding to the expense of an enterprise having several rack cabinets containing many of the electronic systems in a dense configuration.

### BRIEF DESCRIPTION OF THE DRAWINGS

FIG. 1 is a perspective view of an exemplary environment of rack cabinets of electronic devices and cooling systems incorporating an embodiment of the present invention.

FIG. 2 is a simplified schematic of an exemplary cooling system for use in the environment shown in FIG. 1 along with heat generating components of an electronic system and incorporating an embodiment of the present invention.

FIG. 3 is a flow chart of a simplified procedure for controlling the cooling system shown in FIG. 2 incorporating an embodiment of the present invention.

### DETAILED DESCRIPTION

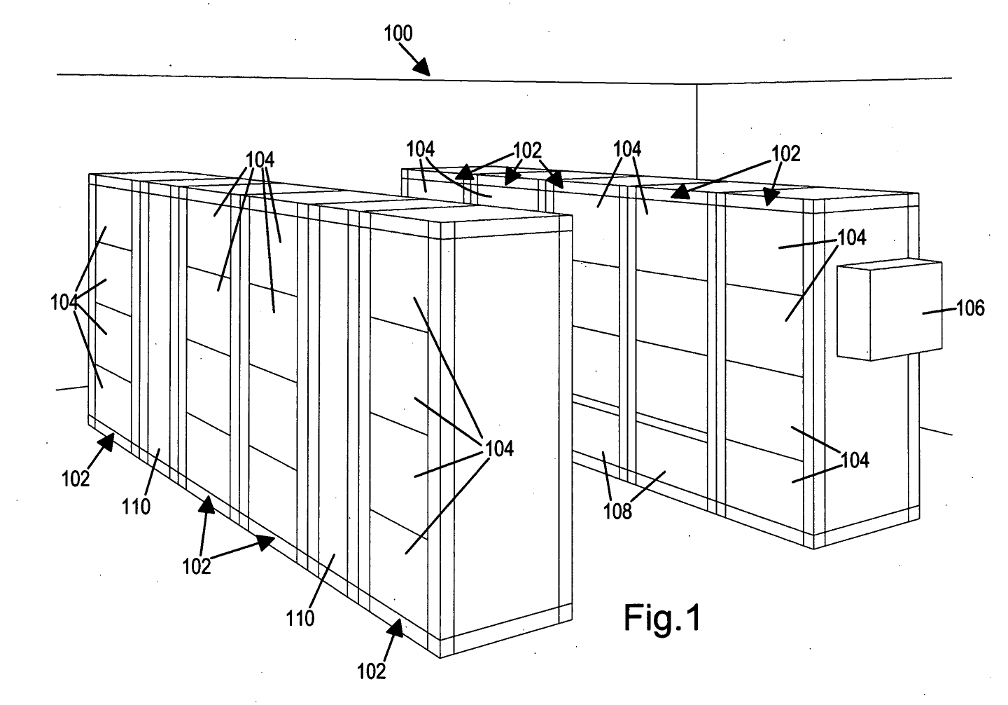

An exemplary room 100 having a rack-based environment with several rack cabinets 102 containing electronic systems 104, such as computers, servers, other computer related devices, etc., is shown in FIG. 1. A variety of different configurations of cooling systems 106-110 are shown among the rack cabinets 102. The cooling systems 106-110 incorporate embodiments of the present invention (as described below). In general, the cooling systems 106-110 are controlled in a manner that prevents most, if not all, condensation in the room 100, the rack cabinets 102, the electronic systems 104 or the cooling systems 106-110. Thus, the need for a means to capture and remove water from the room 100 is minimized or eliminated, thereby simplifying and reducing the cost of installing and maintaining the electronic systems 104 and the rack cabinets 102 in the room 100.

The cooling systems 106-110 illustrate different configurations. For instance, the cooling system 106 is mounted on a side of one of the rack cabinets 102. Alternatively, the cooling systems 108 are each mounted inside one of the rack cabinets 102. In yet another configuration, the cooling systems 110 are installed between rack cabinets 102. The cooling systems 106 and 108, thus, preferably provide cooling air to the electronic systems 104 in the rack cabinets 102 on which or in which the cooling systems 106 and 108 are mounted. On the other hand, the cooling systems 110 preferably provide cooling air to the electronic systems 104 of either or both of the rack cabinets 102 between which the cooling systems 110 are installed. Other configurations of cooling systems located at any appropriate point within the room 100 are possible. For example, such cooling systems may be mounted on top of the rack cabinets 102, under the floor of the room 100, free-standing and offset to the side of the rack cabinets 102, outside of the room 100, etc. For simplicity, only one of the cooling systems (106) will be used for the discussion below. However, it is understood that the following discussion applies to any appropriate cooling system having the features and/or functions described.

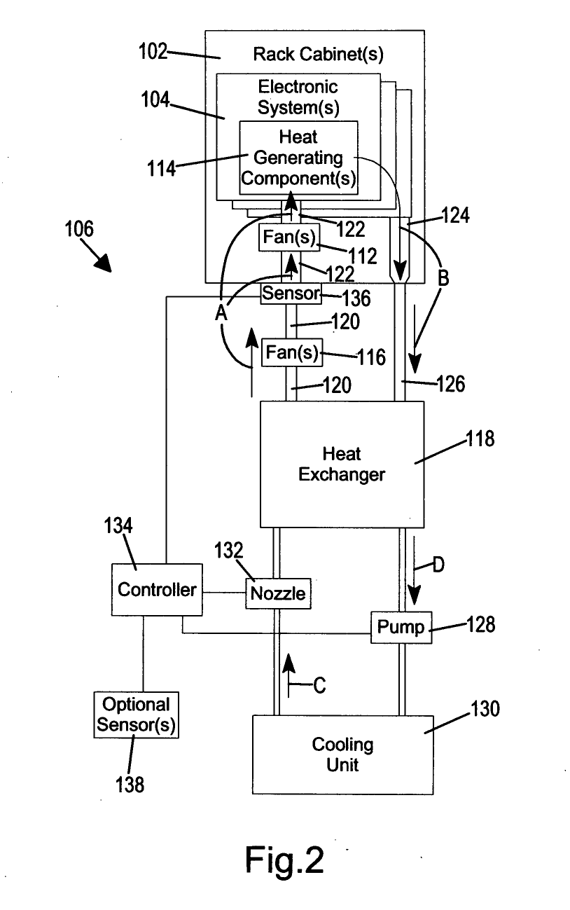

The cooling system 106 is used to cool down air that is forced by fan(s) 112 to flow across the heat generating components 114 of the electronic systems 104 within the rack cabinets 102, as shown in FIG. 2. The air is forced by fan(s) 116 to flow (arrows A) in a path from a heat exchanger 118 in the cooling system 106 through air passageways 120 to the rack cabinets 102. Additional air passageways 122 (e.g. baffles, ducts, conduits, walls, etc.) and the fans 112 in the rack cabinets 102 guide and push the air to the electronic systems 104. Within the electronic systems 104, heat is transferred from the heat generating components 114 to the air. The heated air leaves the electronic systems 104 and passes (arrows B) through additional air passageways 124 and 126 back to the heat exchanger 118.

The cooling system 106 generally includes the heat exchanger 118, a pump 128, a cooling unit 130, an adjustable cooling fluid flow rate and/or velocity control device (e.g. an adjustable or variable inline nozzle or orifice) 132, a controller 134, a temperature sensor 136, one or more of the fans 116 and one or more optional environmental sensors 138, among other components. A cooling fluid (e.g. water, Freon, etc.) flows (arrows C and D) in a path through the cooling system 106 from the pump 128, through the cooling unit 130, the device 132 and the heat exchanger 118 and back to the pump 128. The pump 128 forces the cooling fluid through this flow path. The device 132 is inline with the cooling fluid flow path and is any appropriate device that can regulate the flow rate and/or the velocity of the cooling fluid. (For simplicity, only “flow rate” will be referred to hereafter, but such references are intended to include velocity where appropriate.) In the cooling unit 130, the temperature of the cooling fluid is reduced. In the heat exchanger 118, heat is transferred from the air to the cooling fluid.

Under control of the controller 134, according to some embodiments, the device 132 varies the amount or degree to which it regulates or restricts the flow of the cooling fluid. (In some situations, it is preferable that the controller 134 cannot cause the device 132 to completely stop the flow rate of the cooling fluid, so some minimum cooling capacity is always established.) Additionally, according to some embodiments, the controller 134 controls the speed at which the pump 128 forces the cooling fluid to flow. Therefore, the controller 134, using the device 132 or the pump 128 or both, controls the flow rate of the cooling fluid and, thus, the amount of cooling provided to the air. (According to some additional embodiments, the controller 134 may control or affect the rate at which one or more of the fans 112 and/or 116 force the air through the heat exchanger 118 and/or the electronic systems 104, thereby further controlling the cooling capacity provided to the heat generating components 114.)

The controller 134 is any appropriate electronic device (e.g. a general-purpose programmable processor, an application specific integrated circuit, etc.) that can perform the functions described herein. Additionally, the controller 134 is connected to the temperature sensor 136 to receive temperature-related data.

The temperature sensor 136 is any appropriate temperature sensitive device that can generate the temperature-related data. The temperature sensor 136 is located at any appropriate point in the flow path of the air. According to some particular embodiments, the temperature sensor 136 is located in the air passageways 120 at an entry point to the rack cabinet 102 or to the electronic systems 104. Thus, data indicative of the temperature of the air at the entry point is generated by the temperature sensor 136 and transmitted to the controller 134.

Based on the temperature data received from the temperature sensor 136, the controller 134 determines whether to adjust the device 132 or the pump 128 or both in order to change the flow rate of the cooling fluid and, thus, the amount of cooling provided to the air. According to various embodiments, the controller 134 compares the temperature to one or more “set point” temperatures in order to make this determination. In other words, the controller 134 controls the device 132 or the pump 128 or both by transmitting signals to these devices to adjust the flow rate of the cooling fluid to maintain the temperature of the air near a set point temperature that is low enough to provide sufficient cooling to the heat generating components 114 and high enough to prevent condensation within the electronic systems 104.

The set point temperature may be an anticipated condensation point temperature, or dew point, for the expected conditions under which the room 100, the rack cabinets 102 or the electronic systems 104 are intended to be maintained. Alternatively, the set point temperature may be a few degrees (C or F) above, but still near, the anticipated condensation temperature. In another alternative, there may be more than one set point temperature (e.g. at least one that is only slightly above the condensation point and at least one other that is significantly above the condensation point). Any configuration or combination of the anticipated condensation temperature and/or the set point temperatures may be used, so that the controller 134 can determine whether the temperature of the air is relatively close to the condensation point (allowing for a “fine-tune” control of the cooling fluid flow rate) or significantly high (requiring maximum cooling capacity).

For instance, if the air temperature is relatively high, then condensation is not an issue. Instead, overheating of the heat generating components 114 must be prevented. Therefore, the controller 134 preferably causes the device 132 or the pump 128 or both to make the cooling fluid flow at a maximum rate in order to obtain maximum cooling of the air. On the other hand, if the air temperature is relatively close to the anticipated condensation temperature, then overheating is not a problem. Instead, the controller 134 preferably makes only minor or incremental adjustments to the device 132 or the pump 128 or both to make the cooling fluid flow at a rate that results in the air temperature staying slightly above the anticipated condensation temperature. In this manner, condensation within the electronic systems 104 is minimized or prevented while ensuring an optimal cooling capacity. In other words, the controller 134 manages the amount of fluid flow and the amount of condensation as a function of the heat load and the condensation temperature. Additionally, thermal stress on the heat exchanger 118 is reduced due to the management of the fluid flow and condensation.

According to some alternative embodiments, the condensation temperature is dynamically calculated based on actual environmental conditions within the room 100, the rack cabinets 102 or the electronic systems 104. In this case, the optional environmental sensors 138 (e.g. humidity sensor, air pressure sensor, etc.) are used to generate environmental data (e.g. relative humidity, barometric pressure, etc.) from which the condensation temperature and/or the set point(s) can be calculated. The environmental sensors 138 are, thus, located within the room 100, the rack cabinets 102 or the electronic systems 104 as needed in order to provide the proper data. In this manner, guesswork is eliminated when determining the condensation temperature and/or the set point(s), and the air temperature can be adjusted with a closer tolerance to the actual condensation temperature and an optimized temperature control.

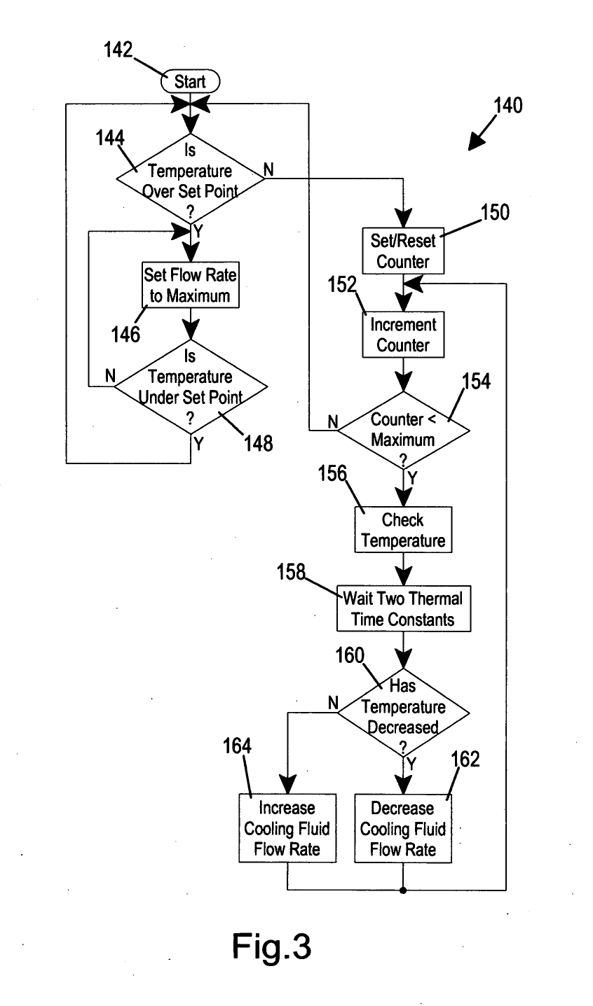

An exemplary procedure 140 by which the controller 134 may cause the device 132 to adjust the flow rate of the cooling fluid is shown by a flowchart in FIG. 3. Alternative procedures by which the controller 134 may cause the device 132, the pump 128 or both to adjust the flow rate of the cooling fluid may be similar. Individual details of such alternative procedures may vary as long as the cooling system primarily maintains the temperature of the air only slightly above the condensation temperature when significant overheating is not an immediate issue.

Upon starting (at 142), the procedure 140 reads the temperature data from the temperature sensor 136 and determines (at 144) whether the temperature of the air is so high that condensation control is not an immediate issue, but that overheating of the heat generating components 114 is an imminent possibility. For example, (at 144) the procedure 140 may compare the air temperature with a set point temperature upper value that is substantially above the anticipated or actual condensation temperature. Alternatively, the procedure 140 may determine (at 144) whether the air temperature is over the condensation temperature by a maximum allowable amount.

If the determination at 144 is positive, then the procedure 140 causes (at 146) the flow rate of the cooling fluid to be set to its maximum level. In other words, the device 132, the pump 128 or both are controlled to allow or cause the flow rate to be at its highest amount. In this manner, maximum cooling capacity is provided to the air and, thus, to the heat generating components 114 when overheating is an immediate issue.

The procedure 140 continues to cause (at 146) the cooling fluid flow rate to be maximized until it is determined (at 148) that the air temperature is under a set point. This set point may be the same as the one used at 142 above. In which case, the determination at 148 may be redundant, so it may be preferable to return to 144 immediately after 146, thereby maintaining the maximum flow rate until the air temperature is below the set point, as determined at 144. Alternatively, the set point used at 148 may be a lower value that is closer to the anticipated or actual condensation temperature than the set point upper value used at 144. By having the second set point used at 148 lower than the first set point used at 144, the maximum cooling is maintained until it is ensured that the potential overheating issue has been thoroughly eliminated.

Upon a positive determination at 148, the procedure 140 returns to 144 to check whether the air temperature is above the first set point, even though the procedure 140 has just determined at 148 that the air temperature is under the second set point. This seeming redundancy in the procedure 140 ensures that the air temperature and the temperature of the heat generating components 114 do not suddenly spike upwards, since overheating must be avoided for proper functioning of the electronic systems 104.

If the determination at 144 is negative, i.e. the air temperature is acceptable, then the procedure 140 branches to 150 to begin a “fine-tuning” control of the cooling fluid flow rate. Beginning at 150, the procedure 140 maintains or adjusts the air temperature as close to the condensation temperature as possible, without going under the condensation temperature and risking water condensation in the electronic systems 104.

At 150, the procedure 140 sets (or resets) a counter. Then the procedure 140 increments the counter at 152. If the counter is less than a maximum count value, as determined at 154, then the procedure 140 continues the “fine-tuning” control of the cooling fluid flow rate at 156. Otherwise, if the determination at 154 is negative, the procedure 140 returns to 144 and continues as described above in order to make sure that the air temperature and the temperature of the heat generating components 114 have not suddenly spiked upwards. In this manner, the procedure 140 performs the “fine-tuning” control only for a selected number of cycles and eventually returns to 144 to make sure that the air temperature is still acceptable.

At 156, the procedure 140 checks the air temperature and stores this information in any appropriate manner. Then the procedure 140 waits (at 158) for a time period. The time period may be any appropriate length that would allow the air temperature sufficient time to change, if it is going to change under current conditions. For example, a time period calculated as two thermal time constants for the mass of the air being cooled may be an appropriate length.

After waiting at 158, the procedure 140 checks the air temperature again and determines (at 160) whether the air temperature has decreased. If so, then it is considered safe to decrease (at 162) the cooling fluid flow rate, so the flow rate is decreased incrementally. In this manner, the cooling capacity is decreased, thereby preventing the air temperature from decreasing too close to the condensation temperature. On the other hand, if the air temperature has not decreased, as determined at 160, then it is preferable to incrementally increase (at 164) the cooling fluid flow rate, if possible.

As an alternative, at 160, the procedure 140 can check whether the air temperature is above a maximum value or below a minimum value. Then if the air temperature is above the maximum value, the cooling fluid flow rate is incrementally increased. But if the air temperature is below the minimum value, the cooling fluid flow rate is incrementally decreased. And if the air temperature is between the maximum and minimum values, then the cooling fluid flow rate is unchanged.

As another alternative, before 160 or during 158, the procedure 140 can perform a check similar to the one at 144 to determine whether the air temperature is unacceptably high. In which case, the heat generating components may be overheating or about to overheat, so the procedure 140 preferably returns to 146 to set the cooling fluid flow rate to maximum. On the other hand, if the air temperature is not too high, based on a determination before 160 or during 158, then the procedure 140 continues at 160 as described above.

In embodiments that use the environmental sensors 138 (FIG. 2), the procedure 140 preferably checks the data from the environmental sensors 138 upon starting at 142. The procedure 140 then dynamically calculates the condensation temperature and/or the set point temperatures described herein. Additionally, the procedure 140 preferably repeats the data check and the calculations as appropriate, e.g. once per day, hour or minute or right before every time the procedure 140 returns to 144.

We claim:

1. A rack-based environment comprising:
a rack cabinet;
electronic systems installed in the rack cabinet and having heat generating components;
a cooling system that cools air that flows through the electronic systems to cool the heat generating components; and
air flow passageways connecting the cooling system to the electronic systems, the air flowing through the air flow passageways from the cooling system to the electronic systems and back;
and wherein the cooling system maintains a temperature of the air near a set point above a condensation point.

2. A rack-based environment as defined in claim 1, wherein:
the cooling system further comprises a cooling fluid in a flow path, a flow rate control device in the flow path, a temperature sensor and a controller;
the temperature sensor is located at a point in the air passageways to generate temperature information for the air; and
the controller is connected to the temperature sensor and the flow rate control device to receive the temperature information and to control the flow rate control device to adjust a flow rate of the cooling fluid to maintain the temperature of the air near the set point.

3. A rack-based environment as defined in claim 2, wherein:
the controller determines whether the temperature of the air is above a certain value; and
when the controller determines that the temperature of the air is not above the certain value, the controller performs cycles of checking the temperature of the air, waiting for a period of time, determining whether the temperature of the air has decreased, decreasing the fluid flow rate when the temperature of the air has decreased, and increasing the fluid flow rate when the temperature of the air has not decreased.

4. A rack-based environment as defined in claim 2, wherein:
the controller causes the flow rate control device to maximize the flow rate of the cooling fluid when the temperature information indicates that the temperature of the air is above a certain value; and
the controller causes the flow rate control device to incrementally change the flow rate of the cooling fluid in accordance with temperature changes when the temperature information indicates that the temperature of the air is below the certain value.

5. A rack-based environment as defined in claim 2, wherein:
the temperature sensor is located at an entry point for the air to pass to the electronic systems.

6. A rack-based environment as defined in claim 2, wherein:
the set point temperature is low enough to provide sufficient cooling to the heat generating components and high enough to prevent condensation within the electronic systems.

7. A rack-based environment as defined in claim 2, wherein:
the controller dynamically calculates the condensation point from data generated by environmental sensors and determines the set point from the condensation point.

8. A cooling system comprising:
a cooling fluid in a flow path;
an air passageway which can connect to an electronic system having heat generating components at which heat can be transferred from the heat generating components to the air, the heat being subsequently transferred to the cooling fluid;
a temperature sensor located in the air passageway to generate temperature information for the air;
a flow rate control device located in the flow path; and
a controller connected to the temperature sensor and the flow rate control device to receive the temperature information and to control the flow rate control device to adjust a flow rate of the cooling fluid to maintain a temperature of the air above a condensation point.

9. A cooling system as defined in claim 8, wherein:
the controller determines whether the temperature of the air is above a certain value; and
when the controller determines that the temperature of the air is not above the certain value, the controller performs cycles of checking the temperature of the air, waiting for a period of time, determining whether the temperature of the air has decreased, decreasing the fluid flow rate when the temperature of the air has decreased, and increasing the fluid flow rate when the temperature of the air has not decreased.

10. A cooling system as defined in claim 9, wherein:
the controller performs the cycles a certain number of times and then again determines whether the temperature of the air is above the certain value.

11. A cooling system as defined in claim 8, wherein:
the controller causes the flow rate control device to maximize the flow rate of the cooling fluid when the temperature information indicates that the temperature of the air is above an upper value; and
the controller causes the flow rate control device to incrementally change the flow rate of the cooling fluid when the temperature information indicates that the temperature of the air is below the upper value.

12. A cooling system as defined in claim 11, wherein:
while the temperature of the air is below the upper value, the controller causes the flow rate control device to incrementally decrease the flow rate of the cooling fluid when the temperature has decreased, and the controller causes the flow rate control device to incrementally increase the flow rate of the cooling fluid when the temperature has increased.

13. A cooling system as defined in claim 11, wherein:
upon maximizing the flow rate of the cooling fluid, the controller causes the flow rate control device to maintain the maximum flow rate until the temperature of the air is below a lower value.

14. A cooling system as defined in claim 8, wherein:
the temperature sensor is located at an entry point for the air to pass into the electronic system.

15. A cooling system as defined in claim 8, wherein:
the controller cannot cause the flow rate control device to stop the flow rate of the cooling fluid.

16. A cooling system as defined in claim 8, wherein:
the controller controls the flow rate control device to adjust the flow rate of the cooling fluid to maintain the temperature of the air near a set point temperature that is low enough to provide sufficient cooling to the heat generating components and high enough to prevent condensation within the electronic system.

17. A cooling system as defined in claim 8, wherein:
the controller dynamically calculates the condensation point from data generated by environmental sensors.

18. A cooling system comprising:
a means for sensing a temperature in an air flow that receives heat from a means for generating heat in an electronic system; and
a means for controlling a flow rate of a cooling fluid that receives the heat from the air flow, the flow rate controlling means responding to the sensed temperature to adjust the flow rate to maintain the temperature of the air near a set point related to a condensation point.

19. A cooling system as defined in claim 18, wherein:
the flow rate controlling means maximizes the flow rate of the cooling fluid when the sensed temperature of the air is above a certain value; and
the flow rate controlling means incrementally changes the flow rate of the cooling fluid when the sensed temperature of the air is below the certain value.

20. A cooling system as defined in claim 18, wherein:
the temperature sensing means is located at an entry point for the air to pass into the electronic system.

21. A cooling system as defined in claim 18, wherein:
the set point temperature is low enough to provide sufficient cooling to the heat generating means and high enough to prevent condensation within the electronic system.

22. A controller, for use in a cooling system for an electronic system, comprising:
a receiver of temperature data generated by a temperature sensor located in an air flow passageway that connects the cooling system to the electronic system, the temperature data indicating the temperature of the air; and
a transmitter of signals to a flow rate control device in a flow path of a cooling fluid in the cooling system, the signals causing the flow rate control device to adjust a flow rate of the cooling fluid for the cooling system to maintain the temperature of the air near and above a condensation point.

23. A controller as defined in claim 22, wherein:
upon receipt of the temperature data from the temperature sensor, the controller determines whether the temperature of the air is above a certain value; and
when the controller determines that the temperature of the air is not above the certain value, the controller performs cycles of checking the temperature of the air, waiting for a period of time, determining whether the temperature of the air has decreased, causing the flow rate control device to decrease the cooling fluid flow rate when the temperature of the air has decreased, and causing the flow rate control device to increase the cooling fluid flow rate when the temperature of the air has not decreased.

24. A controller as defined in claim 22, wherein:
the controller causes the flow rate control device to maximize the flow rate of the cooling fluid when the temperature data indicates that the temperature of the air is above a certain value; and
the controller causes the flow rate control device to incrementally change the flow rate of the cooling fluid when the temperature data indicates that the temperature of the air is below the certain value.

25. A controller as defined in claim 22, wherein:
the controller dynamically calculates the condensation point from data generated by environmental sensors.

26. A method of controlling a cooling system comprising:
determining a temperature of air that flows from the cooling system to an electronic system and back, the air receiving heat from heat generating components within the electronic system; and
adjusting a flow rate of a cooling fluid to maintain the temperature of the air near and above a condensation point, the cooling fluid receiving the heat from the air within the cooling system.

27. A method as defined in claim 26, further comprising:
if the temperature of the air is below a certain value, adjusting the flow rate incrementally according to whether the temperature has decreased since a previous determination of the temperature.

28. A method as defined in claim 27, further comprising:
if the temperature of the air is below the certain value, performing a number of cycles of:
checking the temperature;
waiting for a period of time;
determining whether the temperature has decreased;
upon determining that the temperature has decreased, incrementally decreasing the flow rate of the cooling fluid; and
upon determining that the temperature has not decreased, incrementally increasing the flow rate of the cooling fluid.

29. A method as defined in claim 26, further comprising:
if the temperature of the air is above a certain value, maximizing the flow rate of the cooling fluid to maximize cooling of the air.

30. A method as defined in claim 26, further comprising:
determining the condensation point based on data from environmental sensors.
